(19) United States
(12) Patent Application Publication
(10) Pub. No.: US 2025/0280673 A1
(43) Pub. Date: Sep. 4, 2025

(54) TRANSPARENT DISPLAY APPARATUS

(71) Applicant: LG Display Co., Ltd., Seoul (KR)

(72) Inventors: Dojin KIM, Paju-si (KR); Binn KIM, Paju-si (KR)

(21) Appl. No.: 18/909,792

(22) Filed: Oct. 8, 2024

(30) Foreign Application Priority Data
Feb. 29, 2024 (KR) 10-2024-0029804

(51) Int. Cl. H10K 59/131; H10K 59/35; H10K 59/80

(52) U.S. Cl. CPC H10K 59/131; H10K 59/353; H10K 59/8791

(57) ABSTRACT

A display apparatus according to an exemplary embodiment of the present disclosure is provided. An example transparent display apparatus includes a substrate provided with a plurality of pixels. Each pixel of the plurality of pixels having a transmissive area and a plurality of sub-pixels. The transparent display apparatus includes a non-light emission area on the substrate. The non-light emission area is provided between the transmissive area and the plurality of sub-pixels and the non-light emission area is also provided between the plurality of sub-pixels. The transparent display apparatus includes a plurality of wirings disposed on the non-light emission area. The transparent display apparatus includes a plurality of light blocking members partially overlapping at least a portion of the plurality of wirings from a plan view.

### CROSS-REFERENCE TO RELATED APPLICATIONS

This application claims the benefit of the Korean Patent Applications No. 10-2024-0029804 filed on Feb. 29, 2024, which are hereby incorporated by reference as if fully set forth herein.

### BACKGROUND

### Technical Field

The present disclosure relates to display apparatus, and more particularly, for example, without limitation, a transparent display apparatus displaying images.

### Description of the Related Art

With the advancement of the information age, the demand for a display apparatus for displaying an image has increased in various forms. Therefore, various types of display apparatuses such as a liquid crystal display (LCD) apparatus, a plasma display panel (PDP) apparatus, an organic light emitting display (OLED) apparatus and a quantum dot light emitting display (QLED) apparatus have been recently used.

Recently, studies for a transparent display apparatus in which a user may view objects or images positioned at an opposite side by transmitting the display apparatus are actively ongoing.

As an example, the transparent display apparatus may include a display area, on which an image is displayed, in a substrate, and the display area may include a transmissive area capable of transmitting external light and a non-transmissive area that does not transmit light. As an example, the non-transmissive area may include a plurality of a light emission area in which light is emitted, and a non-light emission area provided between the plurality of the light emission area.

### BRIEF SUMMARY

The plurality of light emission areas is spaced apart from each other with a non-light emission area interposed therebetween, and various wirings for driving the plurality of light emission areas are disposed between the spaced apart light emission areas (or the non-light emission area). Narrow gaps are provided between these wirings so that external light can pass through the narrow gaps. The inventors of the present disclosure have recognized that when external light passes through the narrow gap, a micro diffraction phenomenon occurs, which causes the image quality of the transparent display apparatus to deteriorate. The various embodiments of the present disclosure address one or more technical problems in the related art, including the above-identified problem. For example, various embodiments of a transparent display apparatus is capable of preventing micro diffraction, thereby preventing image quality degradation.

Various embodiments of the present disclosure provide a transparent display apparatus capable of uniformizing the luminance of an image emitted from an edge portion and a center portion of a display panel.

Various embodiments of the present disclosure provide a transparent display apparatus in which a voltage drop in the center portion of a display panel can be prevented, so that the luminance of the edge portion and the center portion of the display panel can be uniformed even with low power, thereby reducing the overall power consumption.

Various embodiments of the present disclosure provide a transparent display apparatus in which coupling between pixels can be prevented during operation.

Various embodiments of the present disclosure provide a transparent display apparatus that can have enhanced transmittance (or transparency).

The technical benefits of the present disclosure are not limited to the above-mentioned benefits, and other benefits, which are not mentioned above, can be clearly understood by those skilled in the art from the following descriptions.

A transparent display apparatus according to an embodiment of the present disclosure comprises a substrate provided with a plurality of pixels having a transmissive area and a plurality of sub-pixels, respectively; a non-light emission area provided to be disposed between the transmissive area and the plurality of sub-pixels and between the plurality of sub-pixels, on the substrate; a plurality of wirings disposed the non-light emission area; and a plurality of light blocking members partially overlapping at least a portion of the plurality of wirings.

### BRIEF DESCRIPTION OF THE SEVERAL VIEWS OF THE DRAWINGS

The accompanying drawings, which are included to provide a further understanding of the disclosure and are incorporated in and constitute a part of this application, illustrate embodiments of the disclosure and together with the description serve to explain the principle of the disclosure. In the drawings:

FIG. 1 is a plan view illustrating a transparent display apparatus according to one embodiment of the present disclosure.

FIG. 2 is a schematic enlargement of portion A of FIG. 1, showing a single pixel.

FIG. 3 is a drawing of FIG. 2 omitting the black matrix and color filter.

FIG. 4 is a schematic cross-sectional view of the line I-I′ shown in FIG. 2.

FIG. 5 is a schematic cross-sectional view of the line II-II′ shown in FIG. 2.

FIG. 6 is a schematic cross-sectional view of the line III-III′ shown in FIG. 2.

FIG. 7 is a plan view illustrating a transparent display apparatus according to another embodiment of the present disclosure.

FIG. 8 is a drawing of FIG. 7 omitting the black matrix and color filter.

FIG. 9 is a schematic cross-sectional view of lines IV-IV′ shown in FIG. 7.

FIG. 10 is a schematic cross-sectional view of the line V-V′ shown in FIG. 7.

### DETAILED DESCRIPTION OF THE DISCLOSURE

Reference will now be made in detail to the embodiments of the present disclosure, examples of which are illustrated in the accompanying drawings. Wherever possible, the same reference numbers will be used throughout the drawings to refer to the same or like parts. Advantages and features of the present disclosure, and implementation methods thereof will be clarified through following embodiments described with reference to the accompanying drawings. The present disclosure may, however, be embodied in different forms and should not be construed as limited to the embodiments set forth herein. Rather, these embodiments are provided so that this disclosure will be thorough and complete, and will fully convey the scope of the present disclosure to those skilled in the art.

A shape, a size, a dimension (e.g., length, width, height, thickness, radius, diameter, area, etc.), a ratio, an angle, and a number disclosed in the drawings for describing embodiments of the present disclosure are merely an example, and thus, the present disclosure is not limited to the illustrated details.

A dimension including size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure.

Like reference numerals refer to like elements throughout. In the following description, when the detailed description of the relevant known function or configuration is determined to unnecessarily obscure the important point of the present disclosure, the detailed description will be omitted.

In a case where ‘comprise,’ ‘have,’ and ‘include’ described in the present specification are used, another part may be added unless ‘only˜’ is used. The terms of a singular form may include plural forms unless referred to the contrary.

In construing an element, the element is construed as including an error range although there is no explicit description.

In describing a position relationship, for example, when a position relation between two parts is described as ‘on˜,’ ‘over˜,’ ‘under˜,’ and ‘next˜,’ one or more other parts may be disposed between the two parts unless ‘just’ or ‘direct’ is used.

In describing a temporal relationship, for example, when the temporal order is described as “after,” “subsequent,” “next,” and “before,” a case which is not continuous may be included, unless “just” or “direct” is used.

It will be understood that, although the terms “first,” “second,” etc., may be used herein to describe various elements, these elements should not be limited by these terms.

These terms are only used to distinguish one element from another. For example, a first element could be termed a second element, and, similarly, a second element could be termed a first element, without departing from the scope of the present disclosure.

“X-axis direction,” “Y-axis direction” and “Z-axis direction” should not be construed by a geometric relation only of a mutual vertical relation and may have broader directionality within the range that elements of the present disclosure may act functionally.

The term “at least one” should be understood as including any and all combinations of one or more of the associated listed items. For example, the meaning of “at least one of a first item, a second item and a third item” denotes the combination of all items proposed from two or more of the first item, the second item and the third item as well as the first item, the second item or the third item.

When it is mentioned that a first element “is connected or coupled to”, “contacts or overlaps” etc. a second element, it should be interpreted that, not only can the first element “be directly connected or coupled to” or “directly contact or overlap” the second element, but a third element can also be “interposed” between the first and second elements, or the first and second elements can “be connected or coupled to”, “contact or overlap”, etc. each other via a fourth element. Here, the second element may be included in at least one of two or more elements that “are connected or coupled to”, “contact or overlap”, etc. each other.

Features of various embodiments of the present disclosure may be partially or overall coupled to or combined with each other and may be variously inter-operated with each other and driven technically as those skilled in the art can sufficiently understand.

The embodiments of the present disclosure may be carried out independently from each other or may be carried out together in co-dependent relationship.

Hereinafter, the preferred embodiments of the present disclosure will be described in detail with reference to the accompanying drawings.

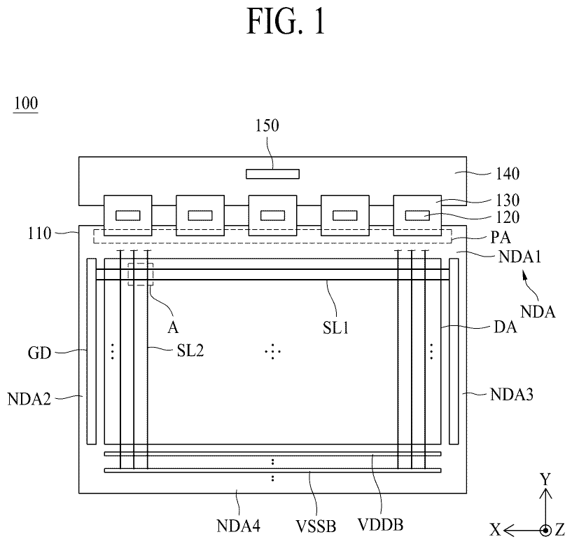

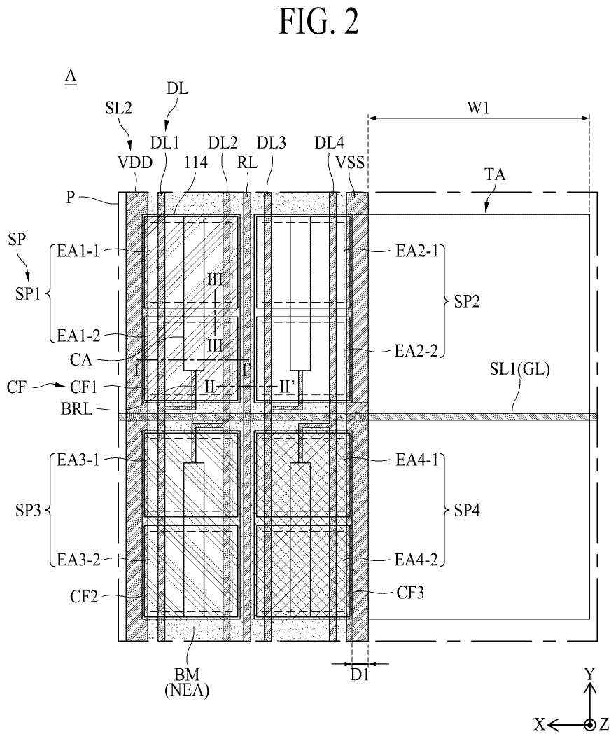

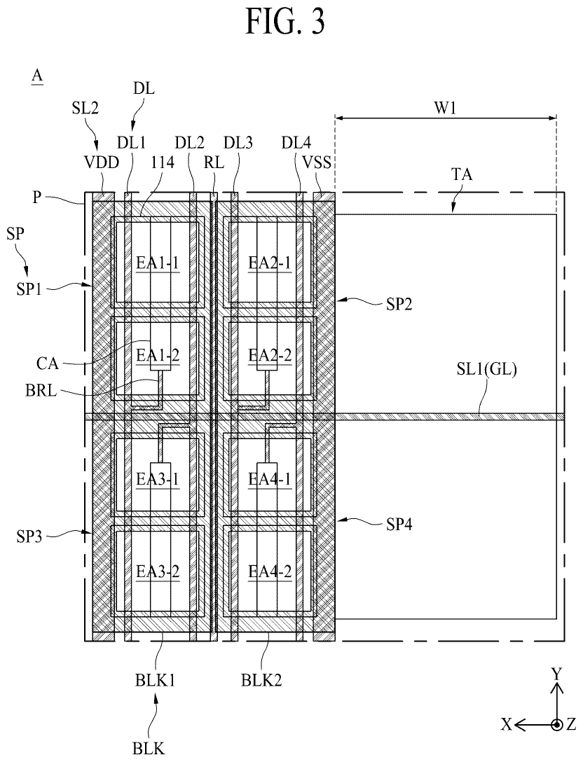

FIG. 1 is a plan view illustrating a transparent display apparatus according to one embodiment of the present disclosure, FIG. 2 is a schematic enlargement of portion A of FIG. 1, showing a single pixel, and FIG. 3 is a drawing of FIG. 2 omitting the black matrix and color filter.

Hereinafter, a first direction (e.g., Y-axis direction) indicates a direction parallel to the data line DL, a second direction (e.g., X-axis direction) indicates a direction parallel to a gate line GL, and a third direction (e.g., Z-axis direction) indicates a thickness direction of the transparent display apparatus 100.

The following description will be based on that a transparent display apparatus 100 according to one embodiment of the present disclosure is an organic light emitting display apparatus, but is not limited thereto. That is, the transparent display apparatus according to one embodiment of the present disclosure may be implemented as any one of a liquid crystal display apparatus, a field emission display apparatus, a quantum dot lighting emitting diode apparatus, a light emitting diode LED display apparatus, a micro-LED display apparatus and an electrophoretic display apparatus as well as the organic light emitting display apparatus.

Referring to FIGS. 1 to 3, the transparent display apparatus 100 according to one embodiment of the present disclosure may include a display panel having a gate driver GD, a source drive integrated circuit (hereinafter, referred to as “IC”) 120, a flexible film 130, a circuit board 140, and a timing controller 150.

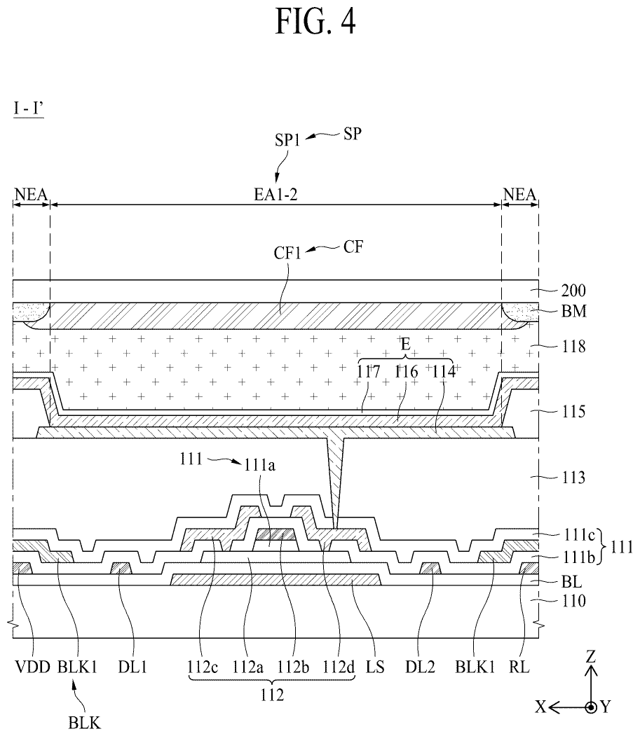

The display panel may include a substrate 110 and an opposite substrate 200 (shown in FIG. 4), which are bonded to each other, without being limited thereto.

The substrate 110 may include a thin film transistor, and may be a transistor array substrate, a lower substrate, a base substrate, or a first substrate. As an example, the substrate 110 may be a transparent substrate. As an example, the substrate 110 may be a transparent glass substrate or a transparent plastic substrate, without being limited thereto.

The opposite substrate 200 may be bonded to the substrate 110, for example, via an adhesive member. For example, the opposite substrate 200 may have a size smaller than that of the substrate 110, or may have a size equal to or greater than that of the substrate 110. As an example, the opposite substrate 200 may be bonded to the remaining portion except the pad area of the substrate 110. The opposite substrate 200 may be an upper substrate, a second substrate, or an encapsulation substrate. Hereinafter, the opposite substrate 200 will be defined as a second substrate.

The gate driver GD supplies gate signals to the gate lines in accordance with the gate control signal input from the timing controller 150. When the source drive IC 120 is manufactured as a driving chip, the source drive IC 120 may be packaged in the flexible film 140 in a chip on film (COF) method or a chip on plastic (COP) method.

Pads such as power pads and data pads may be formed in a non-display area of a display panel. A flexible film 130 may include lines connecting the pads to a source drive IC 120 and/or lines connecting the pads to lines of a circuit board 140. The flexible film 130 may be attached to the pads, for example, by using an anisotropic conducting film, whereby the pads may be connected to the lines of the flexible film 130.

Referring to FIG. 1, the substrate 110 according to an example may include a display area DA and a non-display area NDA.

The display area DA is an area where an image is displayed, and may be a pixel array area, an active area, a pixel array unit, a display unit, or a screen. For example, the display area DA may be disposed at a central portion of the display panel, without being limited thereto. As an example, the display area DA may be biased from the central portion of the display panel, or may be disposed on the entire display panel with the non-display area NDA omitted or invisible from a front side of the display panel (for example, by being bent toward a rear side of the display panel).

The display area DA according to an example may include gate lines, data lines, pixel driving power lines, and a plurality of pixels P (shown in FIG. 2). Each of the plurality of pixels P may include a plurality of sub-pixels SP that may be defined by the gate lines and the data lines, and a transmissive area TA disposed to be adjacent to at least one or some or all of the plurality of sub-pixels SP. The transmissive area TA is an area provided to allow light to transmit front and rear surfaces of the display panel. Therefore, a user located in the direction of the front surface of the display panel may view an image or background positioned in the direction of the rear surface of the display panel through the transmissive area TA.

Each of the plurality of sub-pixels SP may be defined as a minimum unit area in which light is actually emitted.

As an example, at least one sup-pixel or multiple subpixels emitting the same or different colors may be disposed in one unit pixel P. According to one example, at least four sub-pixels, which are provided to emit light of different colors and disposed to be adjacent to one another, among the plurality of sub-pixels SP, and one transmissive area TA constitute one unit pixel P. As an example, one transmissive area TA included in the unit pixel may be disposed to be divided into a plurality of areas, without being limited thereto. One unit pixel may include, but is not limited to, a red sub-pixel, a green sub-pixel, a blue sub-pixel, a white sub-pixel and a transmissive area TA. According to another example, three sub-pixels SP, which are provided to emit light of different colors and disposed to be adjacent to one another, among the plurality of sub-pixels SP, and one transmissive area TA constitute one unit pixel. According to another example, one unit pixel may include at least one red sub-pixel, at least one green sub-pixel, at least one blue sub-pixel and one transmissive area TA, but is not limited thereto. As an example, a sub-pixel of other colors other than red, green, blue, and white may be alternatively or additionally included.

Each of the plurality of sub-pixels SP may include a thin film transistor and a light emitting element connected to the thin film transistor. The sub-pixel may include a light emitting layer (or an organic light emitting layer) interposed between a first electrode and a second electrode.

The light emitting layer disposed in each of the plurality of sub-pixels SP may individually emit light of different colors, or may commonly emit white light. According to one example, when the light emitting layer of each of the plurality of sub-pixels SP commonly emits white light, each of the red sub-pixel, the green sub-pixel and the blue sub-pixel may include a color filter (or a wavelength conversion member) for converting the white light into light of different colors. In this case, the white sub-pixel according to one example may not include a color filter. The color filter CF, according to one example, can include a red color filter CF1, a blue color filter CF2, and a green color filter CF3, without being limited thereto.

In the transparent display apparatus 100 according to one embodiment of the present disclosure, an area in which a red color filter CF1 is provided may be a red sub-pixel SP1, an area in which a blue color filter CF2 is provided may be a blue sub-pixel SP3, an area in which a green color filter CF3 is provided may be a green sub-pixel SP4, and an area in which a color filter is not provided may be a white sub-pixel SP2. In the present disclosure, the red sub-pixel SP1 may be expressed as a first sub-pixel provided to emit red light, the blue sub-pixel SP3 may be expressed as a third sub-pixel configured to emit blue light, the green sub-pixel SP4 may be expressed as a fourth sub-pixel provided to emit green light, and the white sub-pixel SP2 may be represented as a second sub-pixel provided to emit white light.

Each of the plurality of sub-pixels SP supplies a predetermined current to the organic light emitting element in accordance with a data voltage of the data line when a gate signal is input from the gate line by using the thin film transistor. For this reason, the light emitting layer of each of the sub-pixels may emit light with a predetermined brightness in accordance with the predetermined current.

Meanwhile, each of the plurality of sub-pixels SPs emitting different colors can have the same shape and size, as shown in FIG. 2 and can include two light emission areas spaced apart from each other. For example, it can include a first light emission area and a second light emission area. The first sub-pixel SP1 according to an example can include a first light emission area EA1-1 and a second light emission area EA1-2 spaced apart from each other, for example, in the first direction (Y-axis direction). Also, since the first sub-pixel SP1 emits red light, it can include a first color filter CF1 disposed to extend from the first light emission area EA1-1 to the second light emission area EA1-2. The second sub-pixel SP2 according to an example can include a first light emission area EA2-1 and a second light emission area EA2-2 spaced apart from each other, for example, in the first direction (Y-axis direction). The second sub-pixel SP2 can emit white light, and thus can not include a color filter. The third sub-pixel SP3 according to an example can include a first light emission area EA3-1 and a second light emission area EA3-2 spaced apart from each other, for example, in the first direction (Y-axis direction). Also, since the third sub-pixel SP3 emits blue light, it can include a second color filter CF2 disposed to extend from the first light emission area EA3-1 to the second light emission area EA3-2. The fourth sub-pixel SP4 according to an example can include a first light emission area EA4-1 and a second light emission area EA4-2 spaced apart from each other, for example, in the first direction (Y-axis direction). Also, since the fourth sub-pixel SP4 emits green light, it can include a third color filter CF3 disposed to extend from the first light emission area EA4-1 to the second light emission area EA4-2. Embodiments are not limited thereto. As an example, each of the plurality of sub-pixels SPs emitting different colors can have the different shapes and/or sizes. As an example, each of the plurality of sub-pixels SPs emitting different colors can have the same or different number of light emission areas, for example, one light emission area, two light emission areas or three or more light emission areas. As an example, two or more light emission areas included in at least one or each of the plurality of sub-pixels SPs may be spaced apart from each other in a direction other than the first direction (Y-axis direction).

As shown in FIG. 2, the display area DA includes a transmissive area TA and a non-light emission area NEA. The transmissive area TA is an area through which most (e.g., more than 90%, 80%, 70%, etc.) of light incident from the outside passes, and the non-light emission area NEA is an area that does not transmit most of light incident from the outside. For example, the non-light emission area NEA can be an area other than the light emission area EA from which light is emitted. In one example, the non-light emission area NEA can be provided on the substrate 110 between the transmissive area TA and the plurality of sub-pixels SP, and between the plurality of sub-pixels SP.

In the non-light emission area NEA, the plurality of pixels P and a plurality of wirings for driving each of the plurality of pixels P can be disposed. The plurality of wirings, according to one example, can include a plurality of first signal lines SL1 and a plurality of second signal lines SL2.

The plurality of first signal lines SL1 may be extended in the second direction (X-axis direction). Each of the plurality of first signal lines SL1 may include at least one scan line.

Hereinafter, when the first signal line SL1 includes a plurality of lines, one first signal line SL1 may refer to a signal line group comprised of a plurality of lines. For example, when the first signal line SL1 includes two scan lines, one first signal line SL1 may refer to a signal line group comprised of two scan lines.

The plurality of second signal lines SL2 can extend in the first direction (Y-axis direction). The plurality of second signal lines SL2 can intersect with the plurality of first signal lines SL1. Each of the plurality of second signal lines SL2 can include a pixel power line VDD, and a common power line VSS disposed spaced apart from the pixel power line VDD. In an embodiment, the plurality of second signal lines SL2 can further include a plurality of data lines DL, and a reference line RL. The plurality of data lines DL can include a first data line DL1 for driving a first sub-pixel SP1, a second data line DL2 for driving a second sub-pixel SP2, a third data line DL3 for driving a third sub-pixel SP3, and a fourth data line DL4 for driving a fourth sub-pixel SP4.

Hereinafter, when the second signal line SL2 includes a plurality of lines, one second signal line SL2 may refer to a signal line group comprised of a plurality of lines. For example, when the second signal line SL2 includes four data lines, a pixel power line, a common power line and a reference line, one second signal line SL2 may refer to a signal line group comprised of four data lines, a pixel power line, a common power line and a reference line.

At least one transmissive area TA may be disposed between the first signal lines SL1 adjacent to each other. In addition, at least one transmissive area TA may be disposed between the second signal lines SL2 adjacent to each other. That is, the transmissive area TA may be surrounded by two first signal lines SL1 and two second signal lines SL2. However, it is not limited thereto, depending on the arrangement structure of the wiring, the first signal line SL1 (and/or the second signal line SL2) can be provided to cross the transmissive area TA, as shown in FIG. 2.

Referring back to FIG. 1, the non-display area NDA is an area on which an image is not displayed, and may be a peripheral circuit area, a signal supply area, an inactive area or a bezel area. The non-display area NDA may be configured to be in the vicinity of the display area DA. That is, the non-display area NDA may be disposed to fully or partially surround the display area DA.

The transparent display apparatus 100 according to one embodiment of the present disclosure can include a pad portion PA disposed in the non-display area NDA. The pad portion PA can be for driving the plurality of pixels P. For example, the pad portion PA can supply power and/or signals for the plurality of pixels P disposed in the display area DA to output images. As an example, the non-display area NDA can include a first non-display area NDA1, a second non-display area NDA2, a third non-display area NDA3, and a fourth non-display area NDA4, without being limited thereto. The pad portion PA according to one example can be disposed in the first non-display area NDA1, or may be disposed in one or more of the first non-display area NDA1, the second non-display area NDA2, the third non-display area NDA3, and the fourth non-display area NDA4. As an example, one or more of the first non-display area NDA1, the second non-display area NDA2, the third non-display area NDA3, and the fourth non-display area NDA4 may be omitted or invisible from the front side of the display panel.

The gate driver GD supplies gate signals to the gate lines in accordance with the gate control signal input from the timing controller 150. The gate driver GD may be formed on one side of the display area DA of the display panel or on the non-display area NDA outside both sides of the display area DA in a gate driver in panel (GIP) method as shown in FIG. 1. Alternatively, the gate driver GD may be manufactured as a driving chip, packaged in a flexible film and attached to the non-display area NDA outside one side or both sides of the display area DA of the display panel by a tape automated bonding (TAB) method. Alternatively, the gate driver GD may be attached to the non-display area NDA outside one side or both sides of the display area DA of the display panel using a chip-on-glass (COG) or chip-on-panel (COP) method, without being limited thereto.

The plurality of gate drivers GD may be separately disposed on a left side of the display area DA, that is, the second non-display area NDA2 and a right side of the display area DA, that is, the third non-display area NDA3. According to one example, the plurality of gate drivers GD may be connected to the plurality of pixels P and the plurality of first signal lines SL1 for supplying signals to the plurality of pixels P. The plurality of first signal lines SL1 may include at least one signal line for supplying a signal for driving the pixel P.

The plurality of second signal lines SL2 may be extended in the first direction (Y-axis direction). The plurality of second signal lines SL2 may cross the plurality of first signal lines SL1. The plurality of second signal lines may include a pixel power line VDD and at least one data line to supply a data voltage to the pixel P. Each of the plurality of second signal lines SL2 may be connected to at least one of a plurality of pads, a pixel power shorting bar VDDB or a common power shorting bar VSSB. The pixel power shorting bar VDDB and the common power shorting bar VSSB may be disposed in the fourth non-display area NDA4 that is disposed to face the pad area PA based on the display area DA, or may be disposed in the first non-display area NDA1, without being limited thereto.

The pixels are provided to overlap at least one of the first signal line SL1 or the second signal line SL2 and emit predetermined light to display an image. The light emission area EA may correspond to an area, which emits light, in the pixel P.

Each of the red sub-pixel SP1 (or first sub-pixel SP1), the white sub-pixel SP2 (or second sub-pixel SP2), the blue sub-pixel SP3 (or third sub-pixel SP3), and the green sub-pixel SP4 (or fourth sub-pixel SP4) can comprise at least one or more light emission areas. The at least one light emission area of each of the sub-pixels SP1, SP2, SP3, SP4 can have the same shape and size, but is not necessarily limited thereto.

As shown in FIG. 2, the first sub-pixel SP1 according to one example can include a first light emission area EA1-1 and a second light emission area EA1-2 spaced apart from each other in the first direction (Y-axis direction). The second sub-pixel SP2 according to one example can include a first light emission area EA2-1 and a second light emission area EA2-2 spaced apart from each other in the first direction (Y-axis direction). The third sub-pixel SP3 according to one example can include a first light emission area EA3-1 and a second light emission area EA3-2 spaced apart from each other in the first direction (Y-axis direction). The fourth sub-pixel SP4 according to one example can include a first light emission area EA4-1 and a second light emission area EA4-2 spaced apart from each other in the first direction (Y-axis direction).

The reason why each of the sub-pixels includes two light emission area (or sub-pixel) as described above is that the entire sub-pixel cannot emit light due to a short circuit caused by particles when the particles are deposited on the light emission area (or sub-pixel) during a manufacturing process when one sub-pixel includes only one light emission area. Therefore, in the transparent display apparatus 100 according to one embodiment of the present disclosure, at least two light emission areas are provided in one sub-pixel and a plurality of light emission areas are connected to a driving transistor through each of a plurality of repair lines (not shown), so that a repair line connected to a light emission area in which a defect occurs may be cut when the defect occurs in the light emission area, whereby the other light emission area may emit light to improve light efficiency. For example, two light emission areas disposed in each of the first sub-pixel SP1 to the fourth sub-pixel SP4 can be connected to a driving transistor provided in each of the sub-pixels through repair wiring. Accordingly, as shown in FIG. 2, the first light emission area and the second light emission area disposed in each of the plurality of sub-pixels SP can have a structure connected to one circuit area CA. The circuit area CA according to one example can be disposed extending from the first light emission area to the second light emission area, as shown in FIG. 2. Embodiments are not limited thereto. As an example, the circuit area CA according to one example can be disposed to overlap both of, only one of or neither of the first light emission area and the second light emission area. The driving transistor can be disposed in the circuit area CA. The circuit area CA according to an example can be connected to each of the plurality of data lines DL through a branch wiring BRL. Accordingly, the driving transistor disposed in the circuit area CA can be applied a data voltage for driving each of the plurality of sub-pixels SP through the branch wiring BRL.

Referring back to FIGS. 2 and 3, in the transparent display apparatus 100 according to one embodiment of the present disclosure, the non-light emission area NEA may be provided between the transmissive area TA and the plurality of sub-pixels SP1, SP2, SP3 and SP4 and between the plurality of sub-pixels SP1, SP2, SP3 and SP4 on the substrate 110. Since each of the plurality of sub-pixels includes a first light emission area and a second light emission area, the non-light emission area NEA may be provided between the a first light emission area and a second light emission area.

The non-light emission area NEA may refer to an area that is provided in the display area DA and does not emit light, and may be expressed as a dead zone because it does not emit light. The dead zone according to one example may be an area in which a black matrix and/or a bank is provided, but is not limited thereto, and may refer to an area in which light is not emitted.

The non-light emission area NEA can have the plurality of wirings, for example, first signal lines SL1 and second signal lines SL2 can be disposed. The first signal lines SL1 according to an example can include the gate line GL disposed extending in the second direction (X-axis direction). The second signal lines SL2 according to an example can include the pixel power line VDD, the common power line VSS, the reference line RL, and the plurality of data lines DL, which are extending in the first direction (Y-axis direction).

The transparent display apparatus 100, according to one embodiment of the present disclosure, can include a plurality of light blocking members BLKs that partially overlap at least a portion of the plurality of the wirings.

The plurality of light blocking members BLKs are for reducing or blocking external light passing through narrow gaps (or gaps) between the plurality of wirings. The transparent display apparatus 100 according to one embodiment of the present disclosure can be top-emission type, without being limited thereto. Accordingly, the plurality of light blocking members BLKs can be disposed on at least some of the wiring of the plurality of wirings (or at least some of the wiring of the plurality of wirings disposed in the non-light emission area NEA). For example, the plurality of light blocking members BLKs are disposed upper than the plurality of wirings, e.g., closer to the opposing substrate 200. In one example, the light blocking members BLKs can be provided with an opaque material, such as metal, without being limited thereto. Thus, even when external light incident on the substrate 110 passes through a gap (or narrow gap) between the plurality of wirings, it can be blocked by the plurality of light blocking members BLK.

The plurality of light blocking members BLK according to one example can be disposed overlapping with a portion of the pixel power line VDD, a portion of the reference line RL, a portion of the common power line VSS, and a portion of each of the plurality of data lines DL in a plan view, as shown in FIG. 3. As shown in FIG. 3, a portion of the pixel power line VDD, a portion of the reference line RL, a portion of the common power line VSS, and a portion of each of the plurality of data lines DL can be disposed in the non-light emission area NEA. A plurality of light blocking members BLK (e.g., a first light blocking member BLK1 and a second light blocking member BLK2) can overlap a portion of the pixel power line VDD, a portion of the reference line RL, a portion of the common power line VSS, and a portion of each of the plurality of data lines DL, which are disposed in the non-light emission area NEA thereby blocking external light passing through a narrow gap (or gaps) between the plurality of wirings. As an example, the plurality of light blocking members BLK according to one example can be disposed to overlap with a narrow gap (or gaps) between the plurality of wirings.

Typically, the plurality of wirings can be spaced apart from each other to reduce or prevent signal interference between them. Accordingly, a narrow gap can be formed between the plurality of wirings. When external light passes through the narrow gap, micro-diffraction can occur, causing a blurred background or image on the back of the display panel. Furthermore, when external light passes through the narrow gaps, micro-diffraction can occur, which can reduce the image quality of the image output from the display panel.

However, the transparent display apparatus 100 according to one embodiment of the present disclosure is configured such that the plurality of light blocking members BLKs partially overlap at least a portion of the plurality of wirings in the non-light emission area NEA, so that external light passed through the narrow gap (or gaps) can be blocked by the light blocking members BLKs. Thus, since the transparent display apparatus 100 according to one embodiment of the present disclosure can be reduce or prevented from micro-diffraction by the plurality of light blocking members BLKs, therefore a deterioration of the image quality of the image can be reduce or prevented, and furthermore, a blurred appearance of the background or image can be reduce or prevented.

Referring to FIG. 3, the plurality of sub-pixels SPs can include the first sub-pixel SP1 and the third sub-pixel SP3 spaced apart in the first direction (Y-axis direction), and the second sub-pixel SP2 and the fourth sub-pixel SP4 spaced apart in the second direction (X-axis direction) from each of the first sub-pixel SP1 and the third sub-pixel SP3. The transmissive area TA can be disposed adjacent to each of the second sub-pixel SP2 and the fourth sub-pixel SP4. However, it is not limited thereof, the arrangement structure of the plurality of sub-pixels SPs can be varied depending on the circuit design. For example, the first sub-pixel SP1, the second sub-pixel SP2, the third sub-pixel SP3, and the fourth sub-pixel SP4 can be disposed in a row in the first direction (Y-axis direction) (or the second direction or any other direction), and the transmissive area TA can be disposed adjacent to each of (or at least one of) the first sub-pixel SP1, the second sub-pixel SP2, the third sub-pixel SP3, and the fourth sub-pixel SP4 in the second direction (X-axis direction). Hereinafter, each of the first to fourth sub-pixels SP1, SP2, SP3, SP4 will be described as an example in which the first to fourth sub-pixels SP1, SP2, SP3, SP4 are arranged in a square shape, as shown in FIG. 3. In addition, each of the first to fourth sub-pixels SP1, SP2, SP3, SP4 may be disposed in a square shape, as shown in FIG. 3, without being limited thereto. As an example, each of the first to fourth sub-pixels SP1, SP2, SP3, SP4 may be disposed in a rectangular shape, a circular shape, an oval shape, a polygonal shape, etc. As an example, the first to fourth sub-pixels SP1, SP2, SP3, SP4 may be disposed in the same shape or different shapes. As an example, the transmissive area TA may be disposed in a square shape, a rectangular shape, a circular shape, an oval shape, a polygonal shape, etc., without being limited thereto.

In the transparent display apparatus 100 according to one embodiment of the present disclosure, the plurality of light blocking members BLK can include a first light blocking member BLK1 and a second light blocking member BLK2.

The first light blocking member BLK1 according to one example, can be disposed extending from the first sub-pixel SP1 to the third sub-pixel SP3.

As shown in FIG. 3, the first light blocking member BLK1 can partially or fully overlap the pixel power line VDD in the non-light emission area NEA. For example, the first light blocking member BLK1 can overlap a portion of the pixel power lines VDD disposed in the non-light emission area NEA on the left side of the first light emission area EA1-1 and the second light emission area EA1-2 of the first sub-pixel SP1.

Further, the first light blocking member BLK1 can overlap a portion of the reference line RL (or a left portion of the reference line RL) disposed extending in the first direction (Y-axis direction) between the first sub-pixel SP1 and the second sub-pixel SP2. In addition, the first light blocking member BLK1 can also overlap a portion of the data lines (e.g., a portion of the first data line DL1 and a portion of the second data line DL2) that extend in the first direction (Y-axis direction) between the first light emission area EA1-1 and the second light emission area EA1-2 of the first sub-pixel SP1.

Further, the first light blocking member BLK1 can overlap a portion of the first signal line SL1 (or a portion of the gate line GL) disposed extending in the second direction (X-axis direction) between the first sub-pixel SP1 and the third sub-pixel SP3. In addition, the first light blocking member BLK1 can also overlap a portion of the data lines (e.g., a portion of the first data line DL1 and a portion of the second data line DL2) that extend in the first direction (Y-axis direction) between the first light emission area EA3-1 and the second light emission area EA3-2 of the third sub-pixel SP3.

Thus, as shown in FIG. 3, the first light blocking member BLK1 can be configured in the form of a quadrangle shape (or trapezoid) surrounding the light emission areas of each of the first sub-pixel SP1 and the third sub-pixel SP3

The second light blocking member BLK2 according to one example is disposed spaced apart from the first light blocking member BLK1, and can be disposed extending from the second sub-pixel SP2 to the fourth sub-pixel SP4. For example, the second light blocking member BLK2 can be disposed spaced apart from the first light blocking member BLK1 on a reference line RL disposed between the pixel power line VDD and the common power line VSS.

As shown in FIG. 3, the second light blocking member BLK2 can partially overlap the common power line VSS in the non-light emission area NEA. For example, the second light blocking member BLK2 can overlap a portion of the common power line VSS disposed in the non-light emission area NEA on the right side of the first light emission area EA2-1 and the second light emission area EA2-2 of the second sub-pixel SP2. The right side of the first light emission area EA2-1 and the second light emission area EA2-2 of the second sub-pixel SP2 can refer to a space between each of the first light emission area EA2-1 and the second light emission area EA2-2 of the second sub-pixel SP2 and a transmissive area TA, respectively.

Further, the second light blocking member BLK2 can overlap a portion of the reference line RL (or a right portion of the reference line RL) extending in the first direction (Y-axis direction) between the first sub-pixel SP1 and the second sub-pixel SP2. In addition, the second light blocking member BLK2 can also overlap a portion of the data lines (e.g., a portion of the third data line DL3 and a portion of the fourth data line DL4) that extend in the first direction (Y-axis direction) between the first light emission area EA2-1 and the second light emission area EA2-2 of the second sub-pixel SP2.

Further, the second light blocking member BLK2 can overlap a portion of the first signal line SL1 (or a portion of the gate line GL) extending in the second direction (X-axis direction) between the second sub-pixel SP2 and the fourth sub-pixel SP4. In addition, the second light blocking member BLK2 can also overlap a portion of the data lines (e.g., a portion of the third data line DL3 and a portion of the fourth data line DL4) that extend in the first direction (Y-axis direction) between the first light emission area EA4-1 and the second light emission area EA4-2 of the fourth sub-pixel SP4.

Thus, as shown in FIG. 3, the second light blocking member BLK2 can be configured in the form of a square shape (or trapezoid) surrounding the light emission areas of each of the second sub-pixel SP2 and the fourth sub-pixel SP4.

As a result, in the transparent display apparatus 100 according to one embodiment of the present disclosure, each of the first light blocking member BLK1 and the second light blocking member BLK2 can be provided in a quadrangle shape (or a trapezoidal shape) surrounding the light emission areas of each of the plurality of sub-pixels SP. As an example, in the transparent display apparatus 100 according to one embodiment of the present disclosure, each of the first light blocking member BLK1 and the second light blocking member BLK2 can be disposed in the non-light emission area NEA excluding the light emission areas of each of the plurality of sub-pixels SP. Therefore, in the transparent display apparatus 100 according to one embodiment of the present disclosure, the first light blocking member BLK1 and the second light blocking member BLK2 of the quadrangle shape (or trapezoidal shape) can block external light passing through a narrow gap (or gaps) between the plurality of wirings disposed in the non-light emission area NEA, thereby reducing or preventing a micro-diffraction phenomenon.

On the other hand, since each of the first light blocking member BLK1 and the second light blocking member BLK2 is configured in a quadrangle shape (or a trapezoidal shape), and is spaced apart from each other on the reference line RL, the first light blocking member BLK1 and the second light blocking member BLK2 may have a structural feature having a symmetrical shape with respect to the reference line RL, as shown in FIG. 3. As an example, the first light blocking member BLK1 and the second light blocking member BLK2 may be spaced apart from each other on the center axis of the reference line RL, without being limited thereto. As an example, the first light blocking member BLK1 and the second light blocking member BLK2 may have an asymmetrical shape with respect to the reference line RL. As an example, the first light blocking member BLK1 and the second light blocking member BLK2 may overlap portions having different area of the reference line RL.

In the transparent display apparatus 100 according to one embodiment of the present disclosure, each of the first light blocking member BLK1 and the second light blocking member BLK2 can be provided with an opaque material (e.g., metal). By each of the first light blocking member BLK1 and the second light blocking member BLK2 being provided with metal, external light that passes through the narrow gap between the plurality of wirings can not pass through each of the first light blocking member BLK1 and the second light blocking member BLK2 being provided with metal and can no longer be incident into the interior of the display panel. Furthermore, as an example, external light that has passed through the narrow gap between the plurality of wirings can be reflected by each of the first light blocking member BLK1 and the second light blocking member BLK2 made of metal and emitted back to the outside, without being limited thereto. Thus, the transparent display apparatus 100 according to one embodiment of the present disclosure can be reduced or prevent from being subjected to microdiffraction by external light. Although the first light blocking member BLK1 and the second light blocking member BLK2 have been described above as an example in which each of the first light blocking member BLK1 and the second light blocking member BLK2 is made of metal, it is not limited thereto, and each of the first light blocking member BLK1 and the second light blocking member BLK2 can be made of a different material if it is possible to block external light incident through a gap between the plurality of wirings, for example, they can be made of a n opaque (e.g., black) inorganic or organic material. Hereinafter, it will be described as an example that each of the first light blocking member BLK1 and the second light blocking member BLK2 is provided with a metal.

In the transparent display apparatus 100 according to one embodiment of the present disclosure, as an example, the first light blocking member BLK1 can be electrically connected to the pixel power line VDD thus indirectly connected to the pad portion PA, without being limited thereto. As an example, the second light blocking member BLK2 can be electrically connected to the common power line VSS thus indirectly connected to the pad portion PA, without being limited thereto. In this case, the first light blocking member BLK1 can be utilized as an auxiliary wiring of the pixel power line VDD. Also, the second light blocking member BLK2 can be utilized as an auxiliary wiring of the common power line VSS.

In a general large-area transparent display apparatus, a voltage drop can occur as the voltage supplied from the edge portion of the display panel is applied to the center portion of the display panel. Therefore, a general large-area transparent display apparatus has a problem that the luminance of the image emitted from the edge portion and the center portion of the display panel is uneven. Furthermore, a general large-area transparent display apparatus has the problem that the display panel needs to be driven with high power to solve the above-mentioned problem of uneven luminance of the image, thereby increasing the overall power consumption.

However, the transparent display apparatus 100 according to one embodiment of the present disclosure is provided with the first light blocking member BLK1 and the second light blocking member BLK2 connected to the pixel power line VDD and/or the common power line VSS, since the first light blocking member BLK1 can be utilized as an auxiliary wiring of the pixel power line VDD, and the second light blocking member BLK2 can be utilized as an auxiliary wiring of the common power line VSS, a voltage drop in a center portion of the display panel can be reduced or prevented. Accordingly, the transparent display apparatus 100 according to one embodiment of the present disclosure can be capable of uniformizing the luminance of the image emitted from the edge portion and the center portion of the display panel even though it is provided to be large-area.

Furthermore, the transparent display apparatus 100 according to one embodiment of the present disclosure is provided with the first light blocking member BLK1 and the second light blocking member BLK2 connected to the pixel power line VDD and/or the common power line VSS, so that a voltage drop in the center portion of the display panel can be reduced or prevented, thus the luminance of the edge portion and the center portion of the display panel can be uniformed with low power, therefore, the overall power consumption can be reduced.

Further, the transparent display apparatus 100 according to one embodiment of the present disclosure is configured such that the first light blocking member BLK1 in a quadrangle shape (or a trapezoid shape) is connected to the pixel power line VDD, and the second light blocking member BLK2 in a quadrangle shape (or a trapezoid shape) is connected to the common power line VSS, the first light blocking member BLK1 and the pixel power line VDD can be applied with the same pixel voltage, and the second light blocking member BLK2 and the common power line VSS can be applied with the same common voltage. Thus, the transparent display apparatus 100 according to one embodiment of the present disclosure can be maintained at a constant voltage during driving, so that a coupling phenomenon between different pixels P can be reduced or prevented.

Hereinafter, with reference to FIG. 4, the structure of each of the plurality of sub-pixels SPs will be described in detail. FIG. 4 is a schematic cross-sectional view of the line I-I′ shown in FIG. 2.

Referring to FIG. 4, a transparent display apparatus 100 according to one embodiment of the present disclosure can include a buffer layer BL, a circuit element layer 111, a thin film transistor 112, an overcoat layer 113, a pixel electrode 114, a bank 115, an organic light emitting layer 116, an opposing electrode 117, a filling layer 118, a color filter CF, and a black matrix BM.

In more detail, each of the subpixels SP according to one embodiment may include a circuit element layer 111 provided on an upper surface of a buffer layer BL, including a gate insulating layer 111a, an interlayer insulating layer 111b and a passivation layer 111c, an overcoat layer 113 provided on the circuit element layer 111, a pixel electrode 114 provided on the overcoat layer 113, a bank 115 covering an edge of the pixel electrode 114, an organic light emitting layer 116 on the pixel electrode 114 and the bank 115, an opposing electrode 117 on the organic light emitting layer 116, a filling layer 118 on the opposing electrode 117, and the color filter CF and the black matrix BM on the filling layer 118.

The thin film transistor 112 for driving the subpixel SP may be disposed on the circuit element layer 111. The circuit element layer 111 may be expressed as the term of an inorganic film layer. The buffer layer BL may be included in the circuit element layer 111 together with the gate insulating layer 111a, the interlayer insulating layer 111b and the passivation layer 111c. The pixel electrode 114, the organic light emitting layer 116 and the opposing electrode 117 may be included in the light emitting element layer E.

The buffer layer BL may be formed between the substrate 110 and the gate insulating layer 111a to protect the thin film transistor 112. The buffer layer BL may be disposed on the entire surface (or front surface) of the substrate 110. The pixel power line VDD for pixel driving may be disposed between the buffer layer BL and the substrate 110 or may be disposed between the circuit element layer 111 and the substrate 110. The pixel power line VDD may be disposed below the bank 115 while being spaced apart from the thin film transistor 112. The reference line RL may also be disposed between the buffer layer BL and the substrate 110 or may be disposed between the circuit element layer 111 and the substrate 110. The reference line RL may be disposed in the non-light emission area NEA that does not overlap with the light emission area EA. The buffer layer BL may serve to block diffusion of a material contained in the substrate 110 into a transistor layer during a high temperature process of a manufacturing process of the thin film transistor. Optionally, the buffer layer BL may be omitted in some cases.

The thin film transistor 112 (or a drive transistor) according to an example may include an active layer 112a, a gate electrode 112b, a source electrode 112c, and a drain electrode 112d.

The active layer 112a may include a channel area, a drain area and a source area, which are formed in a thin film transistor area of a circuit area of the subpixel SP. The drain area and the source area may be spaced apart from each other with the channel area interposed therebetween.

The active layer 112a may be formed of a semiconductor material based on any one of amorphous silicon, polycrystalline silicon, oxide, compound and organic material, without being limited thereto.

The gate insulating layer 111a may be formed on the channel area of the active layer 112a. As an example, the gate insulating layer 111a may be formed in an island shape only on the channel area of the active layer 112a, or may be formed on an entire front surface of the substrate 110 or the buffer layer BL, which includes the active layer 112a.

The gate electrode 112b may be formed on the gate insulating layer 111a to overlap the channel area of the active layer 112a.

The interlayer insulating layer 111b may be formed on the gate electrode 112b and the drain area and the source area of the active layer 112a. As in FIG. 4, the interlayer insulating layer 111b may be formed in an entire light emission area, in which light is emitted to the subpixel SP. However, embodiments of the present disclosure are not limited thereto, the interlayer insulating layer 111b may be patterned between the drain electrode 112d and the gate electrode 112b and drain region of the active layer 112a and may be arranged in an island shape, and moreover, may be patterned between the source electrode 112c and the gate electrode 112b and source region of the active layer 112a and may be arranged in an island shape.

The source electrode 112c may be electrically connected to the source area of the active layer 112a through a source contact hole provided in the interlayer insulating layer 111b overlapped with the source area of the active layer 112a. The drain electrode 112d may be electrically connected to the drain area of the active layer 112a through a drain contact hole provided in the interlayer insulating layer 111b overlapped with the drain area of the active layer 112a.

The drain electrode 112d and the source electrode 112c may be made of the same material (e.g., the same metal material), or different materials. For example, each of the drain electrode 112d and the source electrode 112c may be made of a single metal layer, a single layer of an alloy or a multi-layer of two or more layers, which is the same as or different from that of the gate electrode.

In addition, the circuit area may further include first and second switching thin film transistors or more transistors disposed together with the thin film transistor 112, and a capacitor. Since each of the first and second switching thin film transistors is provided on the circuit area of the subpixel SP to have the same or similar structure as that of the thin film transistor 112, its description will be omitted or briefly given. The capacitor (not shown) may be provided in an overlap area between the gate electrode 112b and the source electrode 112c of the thin film transistor 112, which overlap each other with the interlayer insulating layer 111b interposed therebetween, or may be separately provided and connected to the corresponding electrodes of the thin film transistor 112, without being limited thereto.

Additionally, in order to reduce or prevent a threshold voltage of the thin film transistor provided in a pixel area from being shifted by light, the display panel or the substrate 110 may further include a light shielding layer LS provided below the active layer 112a of at least one of the thin film transistor 112, the first switching thin film transistor or the second switching thin film transistor. The light shielding layer may be disposed between the substrate 110 and the active layer 112a to shield light incident on the active layer 112a through the substrate 110, thereby reducing or minimizing a change in the threshold voltage of the transistor due to external light. Also, since the light shielding layer is provided between the substrate 110 and the active layer 112a, the thin film transistor may be mitigated or prevented from being seen by a user.

The passivation layer 111c may be provided on the substrate 110 to cover the pixel area. The passivation layer 111c covers a drain electrode 112d, a source electrode 112c and a gate electrode 112b of the thin film transistor 112, and the buffer layer BL.

On the other hand, as shown in FIG. 4, the pixel power line VDD may be disposed to overlap the bank 115 in the third direction (Z-axis direction), and the reference line RL may overlap or not overlap the bank 115 in the third direction (Z-axis direction), without being limited thereto. The passivation layer 111c may be formed over the circuit area and the light emission area. The passivation layer 111c may be omitted.

The overcoat layer 113 may be provided on the substrate 110 to cover the passivation layer 111c. When the passivation layer 111c is omitted, the overcoat layer 113 may be provided on the substrate 110 to cover the circuit area (or the thin film transistor 112). The overcoat layer 113 may be formed in the circuit area CA in which the thin film transistor 112 is disposed and the light emission area EA. In addition, the overcoat layer 113 may be formed in the other non-display area NDA except a pad area PA of the non-display area NDA and the entire display area DA. For example, the overcoat layer 113 may include an extension portion (or an enlarged portion) extended or enlarged from the display area DA to the other non-display area NDA except the pad area PA. Therefore, the overcoat layer 113 may have a size relatively wider than that of the display area DA, without being limited thereto.

The overcoat layer 113 according to one example may be formed to have a relatively thick thickness, thereby providing a flat surface on the display area DA and the non-display area NDA. For example, the overcoat layer 113 may be made of an organic material such as photo acryl, benzocyclobutene, polyimide and fluorine resin, without being limited thereto.

On the other hand, the upper surface of the overcoat layer 113 can be provided flatly. Accordingly, the pixel electrodes 114 on the overcoat layer 113 can also be provided flatly, and the organic light emitting layer 116 and the opposing electrode 117 formed thereon can also be provided flatly. Since the pixel electrode 114, the organic light emitting layer 116, the opposing electrode 117, that is, the light emitting element layer E is provided to be flat in the light emission area EA, a thickness of each of the pixel electrode 114, the organic light emitting layer 116 and the opposing electrode 117 in the light emission area EA may be uniformly formed. Therefore, the organic light emitting layer 116 may uniformly emit light without deviation in the light emission area EA.

The pixel electrodes 114 according to one example can be formed on the overcoat layer 113. Since a plurality of wirings are disposed between the overcoat layer 113 and the substrate 110, the pixel electrodes 114 can be disposed over the plurality of wirings. The pixel electrode 114 may be connected to a drain electrode or a source electrode of the thin film transistor 112 through a contact hole passing through the overcoat layer 113 and the passivation layer 111c. The one edge portion of the pixel electrode 114 may be covered by the bank 115. The pixel electrode 114 may be made of at least one of a transparent metal material or a semi-transmissive metal material. Embodiments are not limited thereto. As an example, the edge portion of the pixel electrode 114 may be in contact with the bank 115, without being covered by the bank 115. As an example, the pixel electrode 114 may be made of an opaque material, or a conductive material other than metal.

Since the transparent display apparatus 100 according to one embodiment of the present disclosure is top-emission type, as an example, the pixel electrodes 114 can be made of a highly reflective metallic material or a stacked structure of a highly reflective metallic material and a transparent metallic material, without being limited thereto. For example, the first electrode 114 may be formed of a metal material having high reflectance, such as a stacked structure (Ti/Al/Ti) of aluminum and titanium, a stacked structure (ITO/Al/ITO) of aluminum and ITO, an Ag alloy, and a stacked structure (ITO/Ag alloy/ITO) of Ag alloy and ITO, without being limited thereto. The Ag alloy may be an alloy such as silver (Ag), palladium (Pd), and copper (Cu).

Meanwhile, the material constituting the pixel electrode 114 may include MoTi. The pixel electrode 114 may be a first electrode or an anode electrode.

The bank 115 may be an area, which does not emit light, and disposed on one side of the light emission area EA of each of the plurality of sub-pixels SP. For example, the bank 115 may be disposed in the non-light emission area NEA. The bank 115 may be formed to cover a portion of the edge of the pixel electrode 114. Accordingly, the bank 115 may separate the pixel electrode 114 and the opposing electrode 117 in the edge of the pixel electrode 114. The exposed portion of the pixel electrode 114 that is not covered by the bank 115 may be included in the light emitting portion (or light emission area EA).

After the bank 115 is formed, an organic light emitting layer 116 may be formed to cover the pixel electrodes 114 and the bank 115. Thus, the bank 115 may be provided between the pixel electrodes 114 and the organic light emitting layer 116. The bank 115 may be expressed in terms of a pixel-defining membrane. The bank 115 according to one example may comprise organic material and/or inorganic material.

Referring again back to FIG. 4, the organic light emitting layer 116 may be formed on the pixel electrodes 114 and the bank 115. According to one example, the organic light emitting layer 116 may be disposed in the light emission area EA and the non-light emission area NEA. The organic light emitting layer 116 may be provided between the pixel electrode 114 and the opposing electrode 117. Thus, when a voltage is applied to each of the pixel electrode 114 and the opposing electrode 117, an electric field is formed between the pixel electrode 114 and the opposing electrode 117. Therefore, the organic light emitting layer 116 may emit light. The organic light emitting layer 116 may be formed of light emitting layers of a plurality of subpixels SP and optionally a common layer provided on the bank 115.

As an example, the organic light emitting layer 116 according to an embodiment may be provided to emit white light, without being limited thereto. As an example, the organic light emitting layer 116 may include a plurality of stacks which emit lights of different colors. For example, the organic light emitting layer 116 may include a first stack, a second stack, and a charge generating layer (CGL) provided between the first stack and the second stack. The light emitting layer may be provided to emit the white light, and thus, each of the plurality of subpixels SP may include a color filter CF suitable for a corresponding color.

The first stack may be provided on the pixel electrode 114 and may be implemented by a structure where a hole injection layer (HIL), a hole transport layer (HTL), an emission layer (EML (B)), and an electron transport layer (ETL) are sequentially stacked. Embodiments are not limited thereto. As an example, at least one of the hole injection layer (HIL), the hole transport layer (HTL) and the electron transport layer (ETL) may be omitted.

The charge generating layer may supply an electric charge to the first stack and the second stack. The charge generating layer may include an N-type charge generating layer for supplying an electron to the first stack and a P-type charge generating layer for supplying a hole to the second stack. The N-type charge generating layer may include a metal material as a dopant, without being limited thereto.

The second stack may be provided on the first stack and may be implemented in a structure where a hole transport layer (HTL), a yellow-green (YG) emission layer (EML (YG)), an electron transport layer (ETL) and an electron injection layer (EIL) are sequentially stacked. Embodiments are not limited thereto. As an example, at least one of the hole transport layer (HTL), electron transport layer (ETL) and the e electron injection layer (EIL) may be omitted.

In the display apparatus 100 according to an embodiment of the present disclosure, because the organic light emitting layer 116 is provided as a common layer, the first stack, the charge generating layer, and the second stack may be arranged all over the plurality of subpixels SP. The organic light emitting layer 116, according to another example, may be provided in a multiple-stacked structure such as three-stacked structure or a four-stacked structure, depending on the number of stacks stacked. Embodiments are not limited thereto. As an example, the organic light emitting layer 116 may be also provided individually in each sub-pixel or each light emission area EA.

The opposing electrode 117 may be formed on the organic light emitting layer 116. The opposing electrode 117 may be disposed in the light emission area EA and the non-light emission area NEA. As an example, the opposing electrode 117 according to one example may include a metal material or other conductive materials. As an example, the opposing electrode 117 may include a highly reflective metallic material or a stacked structure of a highly reflective metallic material and a transparent metallic material, without being limited thereto. As an example, the opposing electrode 117 may reflect the light emitted from the organic light emitting layer 116 in the plurality of subpixels SP toward the lower surface of the substrate 110. As an example, the display apparatus 100 according to one embodiment of the present disclosure may be implemented as a bottom emission type display apparatus, a top emission type display apparatus or a dual emission type display apparatus.

If the transparent display apparatus 100 according to one embodiment of the present disclosure is top-emission type, the opposing electrodes 117 can be formed of a transparent conductive material TCO such as ITO, IZO, that is capable of transmitting light or a semi-transmissive conductive material TMCM such as magnesium (Mg), silver (Ag), or an alloy of magnesium (Mg) and silver (Ag). Such opposing electrodes 117 can be referred in terms of second electrodes, cathode electrodes.

The filling layer 118 is formed on the opposing electrodes 117. The filling layer 118 serves to reduce or prevent oxygen or moisture from penetrating into the organic light emitting layer 116 and the opposing electrodes 117. To this end, as an example, the filling layer 118 can be configured to include a getter capable of absorbing oxygen or moisture. Alternatively, the filling layer 118 can comprise a plurality of layers including at least one inorganic film and at least one organic film.

On the other hand, as shown in FIG. 4, the filling layer 118 can be disposed not only in the light emission area EA but also in the non-light emission area NEA. The filling layer 118 can be disposed between the opposing electrodes 117 and the opposing substrate 200.

A color filter CF and a black matrix BM can be disposed between the filling layer 118 and the opposing substrate 200. As described above, the white light emitting portion SP2 can not be provided with a color filter since the organic emission layer 116 emits white light. On the other hand, the red sub-pixel SP1 can be provided with the first color filter (or red color filter CF1) between the filling layer 118 and the opposing substrate 200. The blue sub-pixel SP3 can be provided with the second color filter CF2 (or blue color filter CF2) between the filling layer 118 and the opposing substrate 200. The green sub-pixel SP4 can be provided with the third color filter CF3 (or green color filter CF3) between the filling layer 118 and the opposing substrate 200. As shown in FIG. 4, the color filter CF can be configured to partially cover the black matrix BM.

On the other hand, the black matrix BM can be provided between the plurality of sub-pixels SP1, SP2, SP3, SP4 to reduce or prevent color mixing and/or light leakage. However, as shown in FIG. 2, the black matrix BM can not be disposed between the first light emission area and the second light emission area. This is because the first light emission area and the second light emission area are included in sub-pixels that emit light of the same color. For example, the black matrix BM can not be disposed between the first light emission area EA1-1 and the second light emission area EA1-2 of the first sub-pixel SP1, which is a red sub-pixel. Thus, the transparent display apparatus 100 according to one embodiment of the present disclosure can be configured to emit a unified color from each of the plurality of sub-pixels SPs. Embodiments are not limited thereto. As an example, the black matrix BM may be further disposed between the first light emission area and the second light emission area.

The black matrix BM can comprise a black colored material and can be disposed overlapping the bank 115. The area provided with the black matrix BM and/or the bank 115 can be a dead zone or the non-light emission area. The black matrix BM according to an example can be formed on an opposing substrate 200 to overlap at least a portion of the bank 115, thereby reducing the cell gap between the organic light emitting layer 116 and the opposing substrate 200 to reduce or prevent mixing of sub-pixels.

Referring again to FIG. 2, in the transparent display apparatus 100 according to one embodiment of the present disclosure, the black matrix BM can not be disposed between the second sub-pixel SP2, which is a white sub-pixel, and the transmissive area TA. This is because the second sub-pixel SP2 is configured to emit white light, and therefore, even if the black matrix BM is not disposed between the second sub-pixel SP2 and the transmissive area TA, color mixing can not occur. Therefore, the transparent display apparatus 100 according to one embodiment of the present disclosure can have a structural feature in which the black matrix BM is not disposed between the second sub-pixel SP2 and the transmissive area TA. Embodiments are not limited thereto. As an example, the black matrix BM may be further disposed between the second sub-pixel SP2, which is a white sub-pixel, and the transmissive area TA

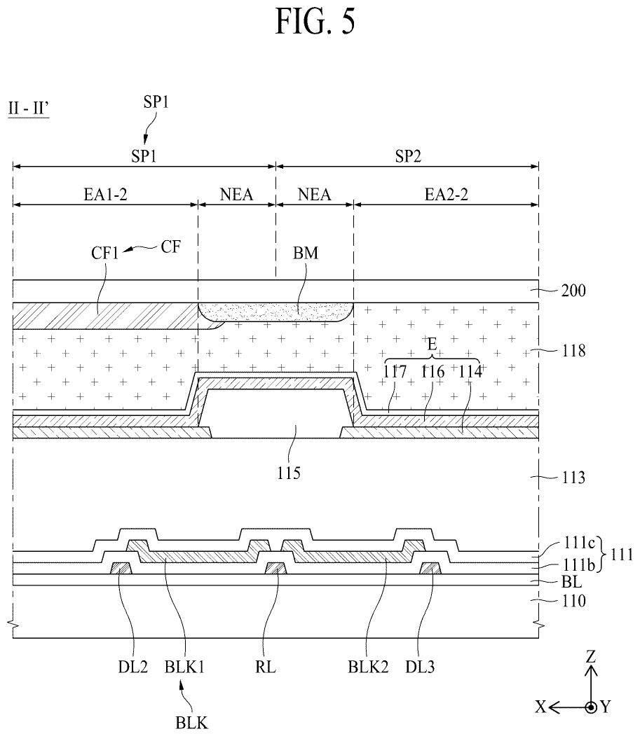

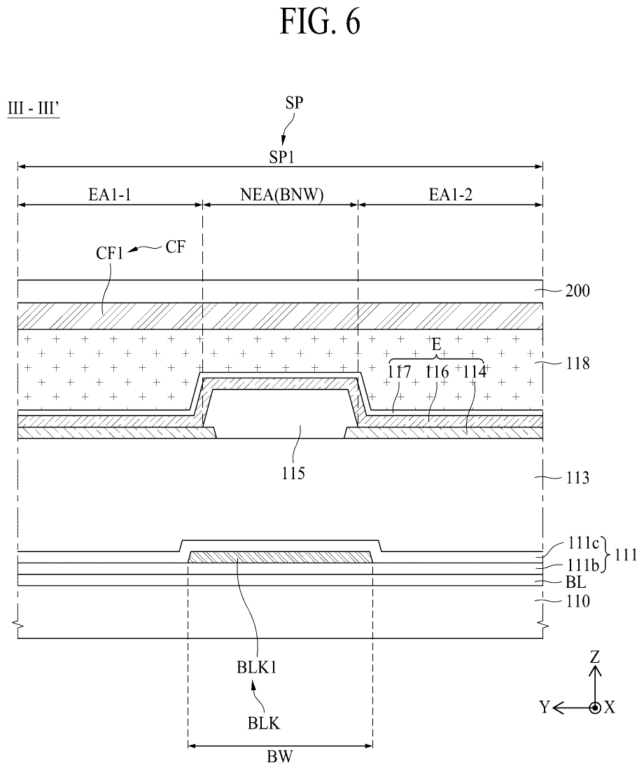

Hereinafter, with reference to FIGS. 5 and 6, the plurality of wirings and the plurality of light blocking members BLKs included in a transparent display apparatus 100 according to one embodiment of the present disclosure will be described in more detail.

FIG. 5 is a schematic cross-sectional view of the line II-II′ shown in FIG. 2, and FIG. 6 is a schematic cross-sectional view of the line III-III′ shown in FIG. 2.

Referring now to FIG. 5, in the transparent display apparatus 100 according to one embodiment of the present disclosure, the black matrix BM can partially overlap each of the first light blocking member BLK1 and/or the second light blocking member BLK2. As described above, each of the first light blocking member BLK1 and the second light blocking member BLK2 is for blocking external light passing between the plurality of wirings disposed in the non-light emission area NEA. Accordingly, each of the first light blocking member BLK1 and the second light blocking member BLK2 can partially overlap at least a portion of the plurality of wirings disposed in the non-light emission area NEA, and the black matrix BM disposed in the non-light emission area NEA can partially overlap each of the first light blocking member BLK1 and/or the second light blocking member BLK2.

For example, as shown in FIG. 5, the black matrix BM disposed between the first sub-pixel SP1 and the second sub-pixel SP2 can overlap a portion of the first light blocking member BLK1 (or a right portion of the first light blocking member BLK1) and a portion of the second light blocking member BLK2 (or a left portion of the second light blocking member BLK2) in the third direction (the Z-axis direction). Thus, the first light blocking member BLK1 and the second light blocking member BLK2 can block external light passing between the second data line DL2 and the reference line RL, and between the third data line DL3 and the reference line RL. Therefore, in the transparent display apparatus 100 according to one embodiment of the present disclosure, the first light blocking member BLK1 and the second light blocking member BLK2 are configured to overlap the wiring of at least a portion of the plurality of wirings, thus a microdiffraction phenomenon caused by external light can be reduced or prevented.

Furthermore, the transparent display apparatus 100 according to one embodiment of the present disclosure is configured such that the black matrix BM partially overlaps each of the first light blocking member BLK1 and/or the second light blocking member BLK2, thus the external light passing between the plurality of wirings can be blocked in duplicate, and thus the reduction or prevention of micro-diffraction phenomena can be increased or maximized.

Furthermore, the transparent display apparatus 100 according to one embodiment of the present disclosure is configured such that the black matrix BM partially overlaps each of the first light blocking member BLK1 and/or the second light blocking member BLK2, therefore, even if the black matrix BM is not exactly disposed in the non-light emission area NEA upon bonding of the substrate 110 and the opposing substrate 200, that is, even if a misalignment with the bank 115 occurs, the first light blocking member BLK1 and/or the second light blocking member BLK2 can cover the non-light emission area NEA, and thus, micro-diffraction phenomena caused by external light can be prevented.

Referring to FIGS. 5 and 6, the transparent display apparatus 100 according to one embodiment of the present disclosure can have the first light blocking member BLK1 and the second light blocking member BLK2, respectively, disposed between the pixel electrode 114 and a plurality of wirings. For example, as shown in FIG. 5, the first light blocking member BLK1 can be partially disposed between a portion of the second data line DL2 and a portion of the pixel electrode 114 of the second light emission area EA1-2 of the first sub-pixel SP1. The second light blocking member BLK2 can be partially disposed between a portion of the third data line DL3 and a portion of the pixel electrodes 114 of the second light emission area EA2-2 of the second sub-pixel SP2. Thus, each of the first light blocking member BLK1 and the second light blocking member BLK2 can partially overlap the pixel electrode 114. Therefore, each of the first light blocking member BLK1 and the second light blocking member BLK2 can block external light passing through a narrow gap (or gaps) between the plurality of wirings.

On the other hand, each of the first light blocking member BLK1 and the second light blocking member BLK2 can be configured to protrude further into the center portion of the pixel electrode 114 (or the center portion of the light emission area) than the bank 115. For example, each of the first light blocking member BLK1 and the second light blocking member BLK2 can be configured to protrude further toward the light emission area EA than the bank 115 so as to partially overlap the light emission area EA. This is so that each of the first light blocking member BLK1 and the second light blocking member BLK2 covers as much as possible the narrow gap (or gaps) between the plurality of wirings to block external light passing through the narrow gap (or gaps). Thus, as shown in FIG. 6, each of the first light blocking member BLK1 and the second light blocking member BLK2 can partially overlap with the color filter CF. In FIG. 5, since the second sub-pixel SP2 does not include a color filter, the second light blocking member BLK2 cannot be partially overlapped with the color filter of the second sub-pixel SP2. However, when the second sub-pixel SP2 includes a color filter, the second light blocking member BLK2 can partially overlap the color filter of the second sub-pixel SP2.

In the transparent display apparatus 100 according to one embodiment of the present disclosure, the first light blocking member BLK1 or the second light blocking member BLK2 can be disposed between a first light emission area and a second light emission area of each of the plurality of sub-pixels SP. For example, as shown in FIG. 6, the first light blocking member BLK1 can be disposed between the first light emission area EA1-1 and the second light emission area EA1-2 of the first sub-pixel SP1. As described above, the transparent display apparatus 100 according to one embodiment of the present disclosure can not have the black matrix BM disposed between the first light emission area and the second light emission area in order to increase the unity of the colors emitted by the one sub-pixel SP. Accordingly, external light can be transmitted between the pixel electrodes 114 of the first light emission area and the pixel electrodes 114 of the second light emission area. However, the transparent display apparatus 100 according to one embodiment of the present disclosure is configured such that the first light blocking member BLK1 or the second light blocking member BLK2 is disposed between the first light emission area and the second light emission area of each of the plurality of sub-pixels SP, thus the external light transmitted between the first light emission area and the second light emission area can be blocked, thereby preventing a micro-diffraction phenomenon.

On the other hand, as shown in FIG. 6, the width BW of the first light blocking member BLK1 or the second light blocking member BLK2 can be equal to or wider than the width BNW of the bank 115. For example, as shown in FIG. 6, the width BW of the first light blocking member BLK1 can be wider than the width BNW of the bank 115. This is because when the width of the first light blocking member or the second light blocking member is narrower than the width of the bank, external light can pass between the first light blocking member or the second light blocking member and the pixel electrode, which can cause a micro-diffraction phenomenon to occur. Therefore, the transparent display apparatus 100 according to one embodiment of the present disclosure is provided with a width BW of the first light blocking member BLK1 or the second light blocking member BLK2 equal to or wider than the width BNW of the bank 115, thus the first light blocking member BLK1 or the second light blocking member BLK2 can cover the gap between the pixel electrodes 114, thereby reducing or preventing a microdiffraction phenomenon.

The transparent display apparatus 100 according to one embodiment of the present disclosure can have the transmissive area TA disposed adjacent to each of the second sub-pixel SP2 and the fourth sub-pixel SP4, as shown in FIG. 2. As described above, the fourth sub-pixel SP4, which is a green sub-pixel, can include a color filter (or the third color filter CF3). Here, the common power line VSS can be thicker than the data line DL to apply a common power to each of the plurality of pixels P in the display area DA, as shown in FIG. 2. Accordingly, the common power line VSS can protrude a first distance D1 from a color filter, for example, the third color filter CF3, to the transmissive area TA. Therefore, the transparent display apparatus 100 according to one embodiment of the present disclosure can be configured such that the transmissive area TA is adjacent to the common power line VSS and has a first width W1.

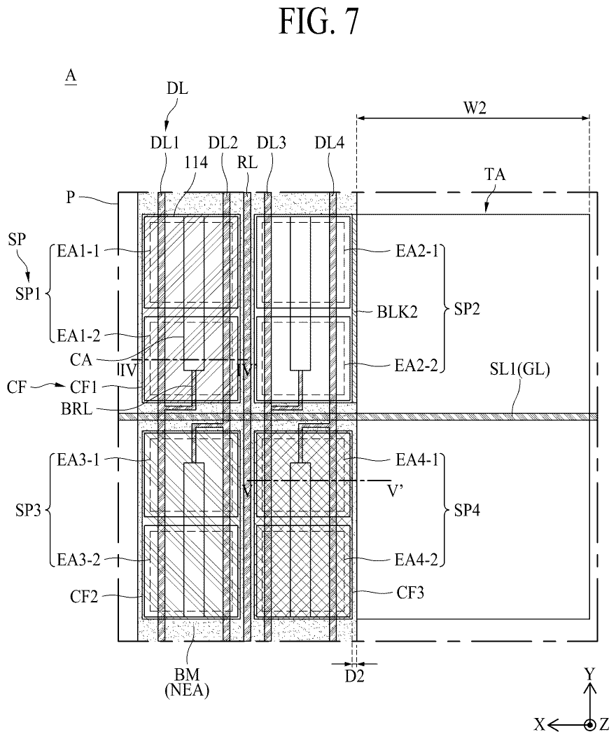

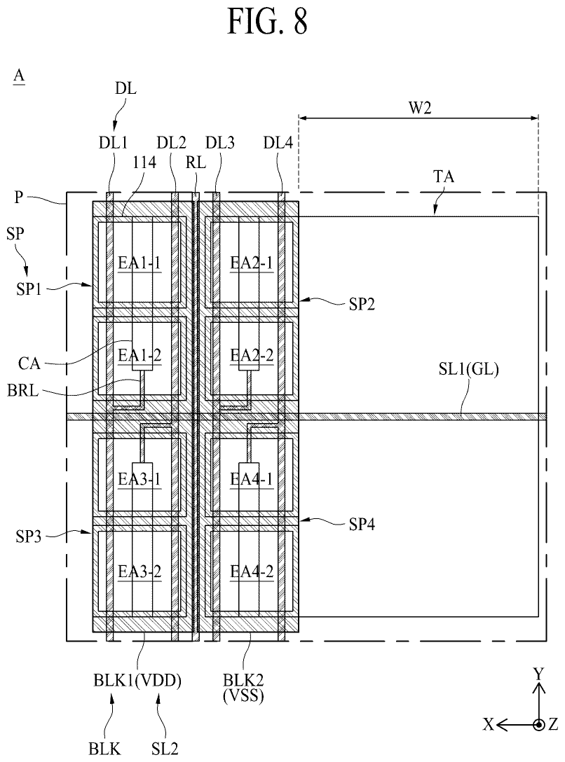

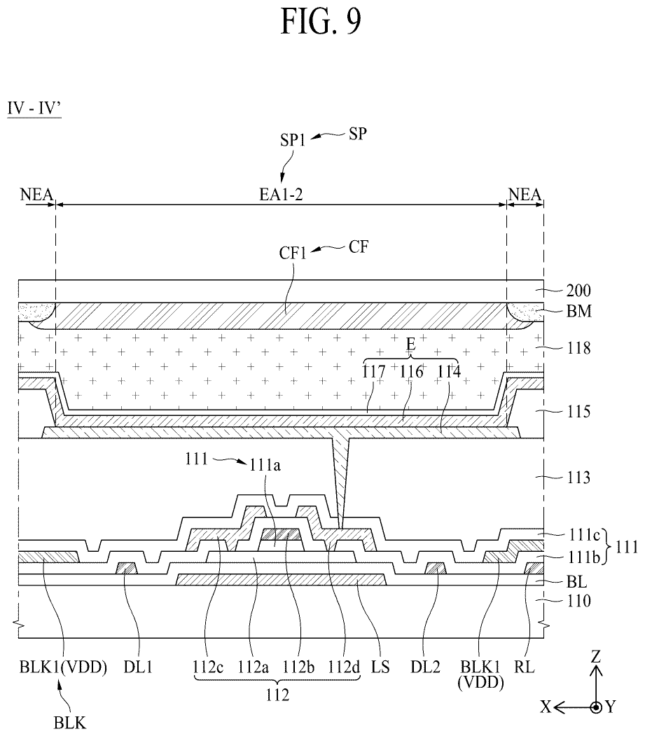

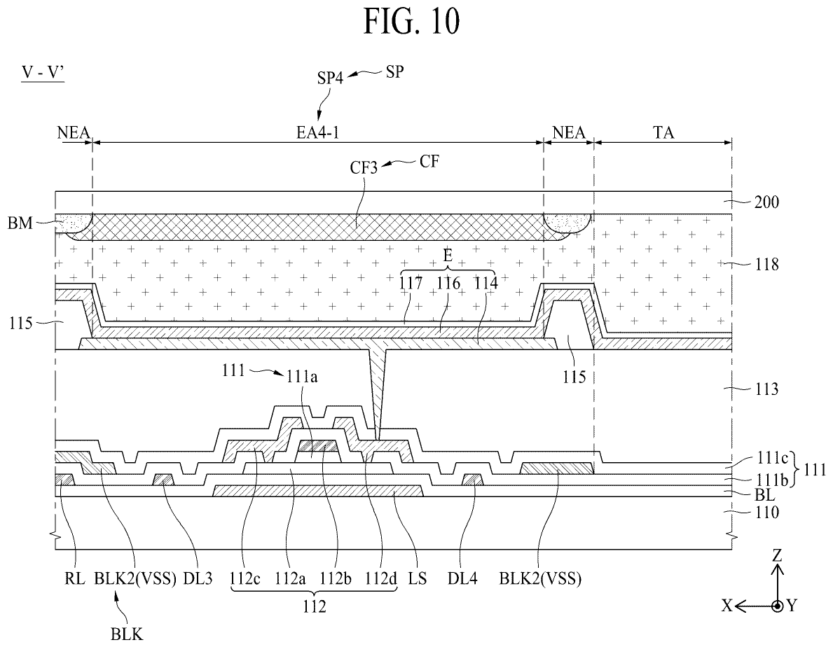

FIG. 7 is a plan view illustrating a transparent display apparatus according to another embodiment of the present disclosure, FIG. 8 is a drawing of FIG. 7 omitting the black matrix and color filter, FIG. 9 is a schematic cross-sectional view of lines IV-IV′ shown in FIG. 7, and FIG. 10 is a schematic cross-sectional view of the line V-V′ shown in FIG. 7.

Referring to FIG. 7, the transparent display apparatus 100 according to another embodiment of the present specification is identical to the transparent display apparatus according to FIG. 1 above, except that the pixel power line VDD and the common power line VSS are omitted, and the connection structure of the first light blocking member BLK1 and the second light blocking member BLK2 is changed. Therefore, the same drawing symbols have been assigned to the same configuration, and only the different configurations will be described hereinafter.

In the case of the transparent display apparatus according to FIG. 1, each of the first light blocking member BLK1 and the second light blocking member BLK2 made of metal is disposed between the plurality of wirings and the pixel electrode 114, and the first light blocking member BLK1 can be electrically connected to the pixel power line VDD thus indirectly connected to the pad portion PA, and the second light blocking member BLK2 can be electrically connected to the common power line VSS thus indirectly connected to the pad portion PA. Accordingly, in the case of the transparent display apparatus according to FIG. 1, when the first light blocking member BLK1 is used as an auxiliary wiring of the pixel power line VDD and the second light blocking member BLK2 is used as an auxiliary wiring of the common power line VSS, a voltage drop in the center portion of the display panel can be reduced or prevented, and thereby, the luminance of the image emitted from the edge portion and the center portion of the display panel can be uniform.

In contrast, in the case of the transparent display apparatus 100 according to FIG. 7 (or the transparent display apparatus 100 according to another embodiment of the present specification), each of the first light blocking member BLK1 (shown in FIG. 8) and the second light blocking member BLK2 can be provided with metal, the first light blocking member BLK1 (shown in FIG. 8) can be directly connected to the pad portion PA, and the second light blocking member BLK2 can be directly connected to the pad portion PA. Thus, the transparent display apparatus 100 according to FIG. 7 can have a structure in which the pixel power line VDD and the common power line VSS are omitted. That is, the transparent display apparatus 100 according to FIG. 7 can be configured so that the first light blocking member BLK1 has the function of the pixel power line VDD and the second light blocking member BLK2 has the function of the common power line VSS. Thus, as shown in FIG. 8, the first light blocking member BLK1 can be assigned with a drawing symbol of VDD, and the second light blocking member BLK2 can be assigned with a drawing symbol of VSS.

On the other hand, there is no black matrix BM between the second sub-pixel SP2 and the transmissive area TA, so that the second light blocking member BLK2 can be shown between the second sub-pixel SP2 and the transmissive area TA in a plan view without the black matrix BM, as shown in FIG. 7.

In the transparent display apparatus 100 according to another embodiment of the present specification, the first light blocking member BLK1 can be thicker (or wider) than the pixel power line VDD of the transparent display apparatus according to FIG. 1 because the first light blocking member BLK1 is quadrangle (or trapezoidal) in shape. Therefore, in the transparent display apparatus 100 according to another embodiment of the present specification, the current density of the first light blocking member BLK1 can be smaller than the current density of the pixel power line VDD of the transparent display apparatus according to FIG. 1 at the same voltage. Therefore, when the current density of the first light blocking member BLK1 of the transparent display apparatus 100 according to another embodiment of the present specification is the same as or similar to the current density of the pixel power line VDD of the transparent display apparatus according to FIG. 1, the width of the first light blocking member BLK1 of the transparent display apparatus 100 according to another embodiment of the present specification can be reduced.

Similarly, since the second light blocking member BLK2 has a quadrangle (or a trapezoidal) shape and can be wider (or thicker) than the common power line VSS of the transparent display apparatus according to FIG. 1. Therefore, in the transparent display apparatus 100 according to FIG. 7, the current density of the second light blocking member BLK2 can be smaller than the current density of the common power line VSS of the transparent display apparatus according to FIG. 1 at the same voltage. Therefore, when the current density of the second light blocking member BLK2 of the transparent display apparatus 100 according to FIG. 7 is the same as or similar to the current density of the common power line VSS of the transparent display apparatus according to FIG. 1, the width of the second light blocking member BLK2 of the transparent display apparatus 100 according to FIG. 7 can be reduced.

Accordingly, since the transparent display apparatus 100 according to other embodiments of the present disclosure can have a reduced width of each of the first light blocking member BLK1 and the second light blocking member BLK2, the extent to which each of the first light blocking member BLK1 and the second light blocking member BLK2 protrudes toward the transmissive area TA can be reduced. For example, as shown in FIG. 7, the second light blocking member BLK2 can protrude a second distance D2 from a color filter, e.g., it can the third color filter CF3, toward the transmissive area TA. Here, the second distance D2 can be smaller than the first distance D1 of the transparent display apparatus of FIG. 1. Thus, the transparent display apparatus 100 according to another embodiment of the present disclosure can be configured to have a second width W2 that is wider than the first width W1 of the transmissive area TA of the transparent display apparatus of FIG. 1 by being configured so that the second light blocking member BLK2 protrudes a second distance D2 that is smaller than the first distance D1 from the color filter (or the third color filter CF3) toward the transmissive area TA. Therefore, the transparent display apparatus 100 according to other embodiments of the present disclosure can have an increased area of the transmissive area TA compared to the transparent display apparatus according to FIG. 1, and thus, the transmissivity (or transparency) can be improved.

Referring to FIG. 9, the transparent display apparatus 100 according to another embodiment of the present disclosure has a structure in which the pixel power line VDD and the common power line VSS are omitted, so that the first light blocking member BLK1 disposed on the pixel power line VDD of the transparent display apparatus of FIG. 1 can be flatly provided. Similarly, as shown in FIG. 10, the second light blocking member BLK2 can be provided flatly. On the contrary, as shown in FIG. 4, since only a portion of the first light blocking member BLK1 overlaps the pixel power line VDD, the first light blocking member BLK1 may not be flatly provided, and could have a stepped portion at an edge of the pixel power line VDD. Similarly, as shown in FIG. 4, the second light blocking member BLK2 may not be provided flatly, and could have a stepped portion at an edge of the common power line VSS, without being limited thereto.

On the other hand, as shown in FIG. 10, in the transparent display apparatus 100 according to another embodiment of the present disclosure, the black matrix BM can be disposed between the fourth sub-pixel SP4, which is a green sub-pixel, and the transmissive area TA. Also, the bank 115 covering the edge of the pixel electrode 114 can be disposed to overlap the black matrix BM. Thus, as shown in FIG. 10, the second light blocking member BLK2 can be partially overlapped each of the black matrix BM and the bank 115 disposed between the fourth sub-pixel SP4 and the transmissive area TA. As a result, the transparent display apparatus 100 according to other embodiments of the present disclosure can have a wider transmissive area TA compared to the transparent display apparatus according to FIG. 1, and thus can have a more improved transmissivity (or transparency).

Further, the transparent display apparatus 100 according to another embodiment of the present disclosure is provided with the first light blocking member BLK1 in a quadrangle shape (or a trapezoid shape) having a function of the pixel power line VDD, and the second light blocking member BLK2 in a quadrangle shape (or a trapezoid shape) having a function of the common power line VSS, thus the reduction or prevention of voltage drop in the center portion of the display panel can be increased or maximized compared to a general transparent display apparatus comprising only the pixel power line and the common power line without the light blocking member, and thereby, the luminance uniformity of the image emitted from the edge portion and the center portion of the display panel can be further improved.

Furthermore, the transparent display apparatus 100 according to another embodiment of the present disclosure is provided with the first light blocking member BLK1 in a quadrangle shape (or a trapezoid shape) having a function of the pixel power line VDD and the second light blocking member BLK2 in a quadrangle shape (or a trapezoid shape) having a function of the common power line VSS, thus reduction or prevention of voltage drop in the center portion of the display panel can be increased or maximized, so that luminance unevenness of the center portion and the edge portion of the display panel can be reduced or prevented even with low power, so that overall power consumption reduction can be increased or maximized.

Embodiments of the present disclosure have been described in more detail with reference to the accompanying drawings, but the present disclosure is not necessarily limited to these embodiments and can be practiced in various modifications without departing from the technical ideas of the present disclosure. Accordingly, the embodiments disclosed herein are intended to illustrate and not to limit the technical ideas of the present disclosure, and the scope of the technical ideas of the present disclosure is not limited by these embodiments. Therefore, the embodiments described above are exemplary in all respects and should be understood as non-limiting. The scope of protection of this specification shall be construed by the claims, and all technical ideas within the scope of the claims shall be construed to be included within the scope of the claims.

In the present disclosure, the light blocking member is configured to partially overlap at least a portion of the plurality of wirings, such that micro-diffraction can be reduced or prevented, thereby reducing or preventing image quality degradation.

In the present disclosure, by providing the light blocking member connected to the pixel power line and/or the common power line, a voltage drop in the center portion of the display panel (or a large-area display panel) can be reduced or prevented, so that the luminance of the image emitted from the edge portion and the center portion of the display panel can be uniform.

In the present disclosure, by providing the light blocking member connected to the pixel power line and/or the common power line, a voltage drop in the center portion of the display panel (or a large-area display panel) can be reduced or prevented, so that the luminance of the edge portion and the center portion of the display panel can be uniformed even with low power, and thus the overall power consumption can be reduced.

In the present disclosure, the light blocking member is provided to be connected to the pixel power line and/or the common power line, so that a coupling phenomenon between the pixels can be reduced or prevented during driving.

In the present disclosure, the light blocking member is configured to have the function of a pixel power line and/or a common power line, such that the pixel power line and/or the common power line disposed between the light emission area and the transmissive area can be omitted, thereby increasing the area of the transmissive area, thereby improving the transmittance (or transparency).

The effects that can be obtained from the present disclosure are not limited to those mentioned above, and other effects not mentioned will be apparent to one having ordinary skill in the art from the following description.

The various embodiments described above can be combined to provide further embodiments. All of the U.S. patents, U.S. patent application publications, U.S. patent applications, foreign patents, foreign patent applications and non-patent publications referred to in this specification and/or listed in the Application Data Sheet are incorporated herein by reference, in their entirety. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display apparatus comprising:
a substrate provided with a plurality of pixels, each pixel of the plurality of pixels having a plurality of sub-pixels;
a non-light emission area on the substrate, the non-light emission area being between the plurality of sub-pixels;
a plurality of wirings on the non-light emission area; and
a plurality of light blocking members partially overlapping at least a portion of the plurality of wirings.

2. The display apparatus of claim 1, wherein the plurality of light blocking members overlaps a gap between the plurality of wirings.

3. The display apparatus of claim 1, wherein each of the plurality of pixels further has a transmissive area, and
wherein the non-light emission area is provided to be further disposed between the transmissive area and the plurality of sub-pixels.

4. The display apparatus of claim 3, wherein the plurality of light blocking members are over at least a portion of the plurality of the wirings.

5. The display apparatus of claim 3,
wherein the plurality of sub-pixels comprise:
a first sub-pixel and a third sub-pixel spaced apart in a first direction, and
a second sub-pixel spaced apart from the first sub-pixel in a second direction and a fourth sub-pixel spaced apart from the third sub-pixel in the second direction,
wherein the plurality of the light blocking members comprise:
a first blocking member disposed to extend from the first sub-pixel to the third sub-pixel, and
a second blocking member disposed to extend from the second sub-pixel to the fourth sub-pixel.

6. The display apparatus of claim 5, wherein each of the first light blocking member and the second light blocking member is provided in a quadrangle shape.

7. The display apparatus of claim 5, wherein the first light blocking member is provided to surround a light emission area of each of the first sub-pixel and the third sub-pixel, and
wherein the second light blocking member is provided to surround a light emission area of each of the second sub-pixel and the fourth sub-pixel.

8. The display apparatus of claim 5, wherein each of the first light blocking member and the second light blocking member is provided in metal.

9. The display apparatus of claim 5,
wherein the plurality of wirings comprise a pixel power line and a common power line spaced apart from the pixel power line, both extending in the first direction,
wherein the first light blocking member partially overlaps the pixel power line, and
wherein the second light blocking member partially overlaps the common power line.

10. The display apparatus of claim 9,
wherein the second blocking member is spaced apart from the first light blocking member,
wherein the first light blocking member is electrically connected to the pixel power line, and
wherein the second light blocking member is electrically connected to the common power line.

11. The display apparatus of claim 9,
wherein the pixel power line is disposed in the non-light emission area on a left side of the first sub-pixel and the third sub-pixel, and
wherein the common power line is disposed in the non-light emission area on a right side of the second sub-pixel and the fourth sub-pixel.

12. The display apparatus of claim 9,
wherein the transmissive area is disposed adjacent to each of the second sub-pixel and the fourth sub-pixel,
wherein the fourth sub-pixel comprises a color filter, and
wherein the common power line protrudes a first distance from the color filter to the transmissive area.

13. The display apparatus of claim 9,
wherein the plurality of wirings further comprise a reference line disposed between the pixel power line and the common power line, and
wherein the first light blocking member is spaced apart from the second light blocking member over the reference line.

14. The display apparatus of claim 13, wherein the first light blocking member and the second light blocking member are symmetrical with respect to the reference line.

15. The display apparatus of claim 5,
wherein each of the plurality of sub-pixels comprises a first light emission area and a second light emission area spaced apart from each other in the first direction, and
wherein the first light blocking member or the second light blocking member is disposed between the first light emission area and the second emission area.

16. The display apparatus of claim 15, further comprising:
a bank disposed between the first light emission area and the second light emission area,
wherein a width of the first light blocking member or the second light blocking member between the first light emission area and the second emission area is either equal to or wider than a width of the bank.

17. The display apparatus of claim 15, further comprising:
a black matrix disposed between the plurality of sub-pixels,
wherein the black matrix is not disposed between the first emission area and the second emission area.

18. The display apparatus of claim 17,
wherein the second sub-pixel is a white sub-pixel, and
wherein the black matrix is not disposed between the second sub-pixel and the transmissive area.

19. The display apparatus of claim 18, wherein the black matrix partially overlaps each of the first light blocking member and/or the second light blocking member.

20. The display apparatus of claim 1,
wherein each of the plurality of sub-pixels comprises a pixel electrode disposed over the plurality of wirings, and
wherein the plurality of light blocking members is disposed between the pixel electrode and the plurality of wirings in a thickness direction of the display apparatus.

21. The display apparatus of claim 20,
wherein the plurality of light blocking members partially overlaps the pixel electrode.

22. The display apparatus of claim 20,
wherein the plurality of light blocking members overlaps a gap between the plurality of wirings and a gap between the plurality of wirings and the pixel electrode.

23. The display apparatus of claim 5,
wherein a part of the plurality of sub-pixels comprises a color filter, and
wherein each of the first light blocking member and the second light blocking member partially overlaps the color filter.

24. The display apparatus of claim 5,
wherein each of the plurality of sub-pixels comprises a pixel electrode disposed over the plurality of wirings, and
wherein the display apparatus further comprises a bank covering an edge of the pixel electrode,
wherein each of the first light blocking member and the second light blocking member further protrudes to the center portion of the pixel electrode than the bank.

25. The display apparatus of one of claim 5,
wherein the substrate comprises a non-display area surrounding the plurality of pixels,
wherein the non-display area comprises a pad portion for driving the plurality of pixels,
wherein each of the light blocking member and the second light blocking member is provided in metal,
wherein the first light blocking member is directly connected to the pad portion, and
wherein the second light blocking member is directly connected to the pad portion.

26. The display apparatus of one of claim 25,
wherein the transmissive area is disposed adjacent to each of the second sub-pixel and the fourth sub-pixel,
wherein the fourth sub-pixel comprises a color filter, and
wherein the second light blocking member protrudes a second distance from the color filter toward the transmissive area.

27. A display apparatus comprising:
a substrate provided with a plurality of pixels each having a plurality of sub-pixels;
a non-light emission area provided to be disposed between the plurality of sub-pixels, on the substrate;
a plurality of wirings disposed in the non-light emission area; and
a pixel power line and a common power line spaced apart from the pixel power line, both disposed in the non-light emission area,
wherein the pixel power line and the common power line overlap a gap between the plurality of wirings.

28. The display apparatus of one of claim 27,
wherein each of the plurality of sub-pixels comprises a pixel electrode disposed over the plurality of wirings, and
wherein the pixel power line and the common power line are disposed between the pixel electrode and the plurality of wirings in a thickness direction of the display apparatus.

29. The display apparatus of one of claim 27,
wherein the pixel power line and the common power line further overlap a gap between the plurality of wirings and the pixel electrode.
